(19) United States
(12) Patent Application Publication
(10) Pub. No.: US 2009/0029522 A1
(43) Pub. Date: Jan. 29, 2009

(54) Method of Forming Isolation Layer of Semiconductor Device

(75) Inventors: Whee Won Cho, Chungcheongbuk-do (KR); Seung Hee Hong, Seoul (KR); Suk Joong Kim, Kyeongki-do (KR); Jong Hye Cho, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/954,470

(22) Filed: Dec. 12, 2007

(30) Foreign Application Priority Data
Jul. 25, 2007 (KR) 2007-74610

(51) Int. Cl. H01L 21/762

(52) U.S. Cl. 438/425; 257/E21.546

(57) ABSTRACT

A method of forming isolation layers of a semiconductor device including forming a first insulating layer on a semiconductor substrate including trenches formed in the semiconductor substrate, substituting a top surface of the first insulating layer with salt, removing the salt to expand a space between sidewalls of the first insulating layer, and forming a second insulating layer on the first insulating layer so that the trenches are gap-filled. Thus, trenches can be easily gap-filled with an insulating material.

### CROSS-REFERENCE TO RELATED APPLICATION

The priority of Korean patent application number 10-2007-74610, filed on Jul. 25, 2007, the entire disclosure which is incorporated by reference, is claimed.

### BACKGROUND OF THE INVENTION

The invention relates to a method of forming isolation layers of a semiconductor device and, more particularly, to a method of forming isolation layers of a semiconductor device to which a shallow trench isolation (STI) process of gap-filling trenches with an oxide layer is applied.

In general, semiconductor devices formed on silicon wafers include isolation regions for electrically isolating respective semiconductor elements. In particular, as semiconductor devices have become more highly integrated and micro in scale, active research has investigated not only reduction of size of individual elements, but also reduction in size of the isolation region. This is because the formation of the isolation region is part of an initial step in the entire fabrication process, and dictates the size of an active region and process margin of subsequent process steps.

In this isolation region, isolation layers are generally formed by an STI method. In this STI method, a nitride film with an etch selectivity different from that of a semiconductor substrate is first formed on the semiconductor substrate. After a nitride film pattern is formed, the semiconductor substrate is etched to a specific depth by an etch process using the nitride pattern as a hard mask, thus forming trenches. The trenches are gap-filled with an insulating material (for example, a high density plasma (HDP) oxide layer, an O₃-tetra ethyl ortho silicate (TEOS) oxide layer, etc.). Thereafter, a polishing process, such as chemical mechanical polishing (CMP), is performed on the insulating material formed on the semiconductor substrate, so that isolation layers are formed in the semiconductor substrate.

However, as process technology for fabricating semiconductor devices is applied on a micro scale, the width of the trench is narrowed and the aspect ratio of the trench is accordingly increased. Thus, the process of gap-filling the trench with the insulating material gradually becomes more difficult. For example, if the trench is gap-filled with the HDP oxide layer, overhang occurs in an opening of the trench due to a redeposition phenomenon, which may hinder the gap-filling of the trench. On the other hand, if the trench is gap-filled with an O₃-TEOS oxide layer, a void or seam is generated within the trench due to slant sidewalls of the trench that are almost vertical. Consequently, defects are generated within the isolation layer. An etchant can be infiltrated into the defects of the isolation layer during a wet etch process that is subsequently performed, so that the isolation layer may be broken.

Meanwhile, there has been proposed a technique of firstly gap-filling the trench with a spin on glass (SOG) oxide layer (i.e., an insulating material having a good step coverage) and then fully gap-filling the trench with a HDP oxide layer, etc. in order to gap-fill the trench more easily. However, since a large amount of impurities are included in the SOG oxide layer, the film quality of the isolation layer may be degraded and a process of removing the impurities must be performed additionally.

### BRIEF SUMMARY OF THE INVENTION

The invention is directed to a method of forming isolation layers of a semiconductor device, in which a part of a trench is gap-filled with a first insulating layer having a thickness such that the shape of the trench can be maintained, a top of the first insulating layer is substituted with a salt, and the a salt is removed, so that a width between the tops of the first insulating layers is expanded and the trench can be easily gap-filled with an insulating material.

In one embodiment, the invention provides a method of forming isolation layers of a semiconductor device, the method comprising: forming a first insulating layer on a semiconductor substrate including on trenches formed in the semiconductor substrate whereby the insulating layer defines sidewalls on the trenches; substituting a top surface of the first insulating layer with a salt; removing the salt to expand a space between the sidewalls of the first insulating layer; and forming a second insulating layer on the first insulating layer in order to gap-fill the trenches.

The salt preferably comprises (NH₄)₂SiF₆. The salt is preferably removed by an annealing process, especially one performed at a temperature of 100 degrees Celsius to 700 degrees Celsius. At least one of the first insulating layer and the second insulating layer is preferably formed of an oxide layer, Highly preferably O₃-TEOS oxide layer. The top surface of the first insulating layer preferably reacts with an etchant and may be substituted with the salt. The etchant is preferably generated by reacting NF₃ with NH₃ in a plasma state. The etchant preferably comprises NH₄F or NH₄F.HF. The formation of the trenches preferably includes forming a tunnel insulating layer and a conductive layer over the semiconductor substrate, and etching the conductive layer, the tunnel insulating layer, and the semiconductor substrate so that the isolation region of the semiconductor substrate is exposed, forming the trenches. The first insulating layer is preferably formed to a thickness in which a shape of the trench can be maintained.

According to the invention, in the method of forming the isolation layers of the semiconductor device, a part of the trenches is gap-filled with the first insulating layer having a thickness in which the shape of the trench can be maintained. The top surface of the first insulating material is removed, and a space between the sidewalls of the first insulating layer is expanded. The trenches are fully gap-filled with the second insulating layer, so that the trenches can be easily gap-filled with an insulating material. Accordingly, a good isolation layer can be formed since defects, such as void and/or seams, are not generated without using a dry etch process.

### BRIEF DESCRIPTION OF THE DRAWINGS

FIGS. 1A to 1G are cross-sectional views illustrating a method of forming isolation layers of a semiconductor device according to the invention.

### DESCRIPTION OF SPECIFIC EMBODIMENTS

Now, a specific embodiment according to the invention will be described with reference to the accompanying drawings.

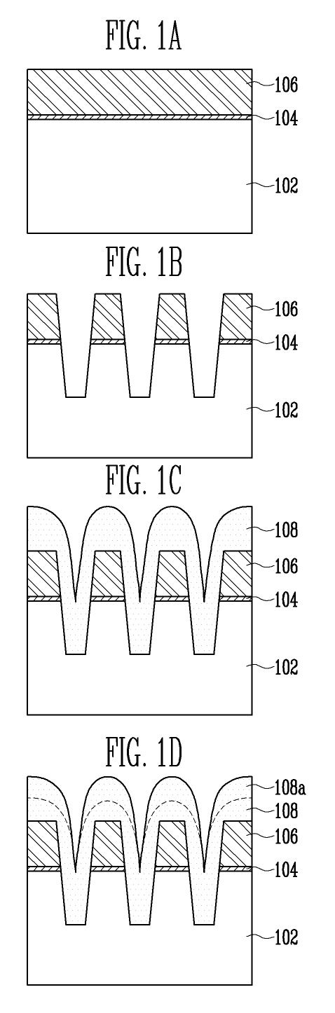

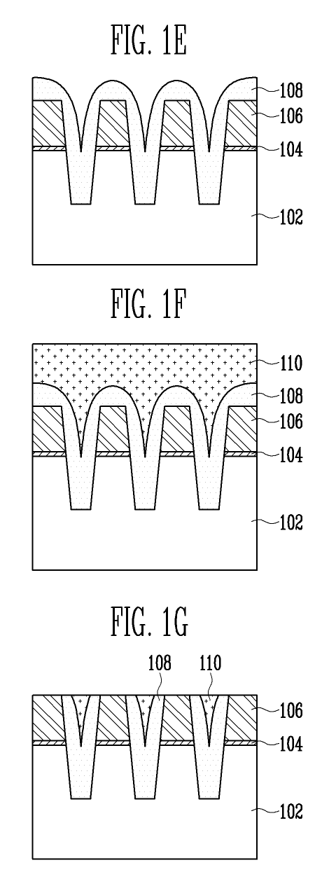

FIGS. 1A to 1G are cross-sectional views illustrating a method of forming isolation layers of a semiconductor device according to the invention.

Referring to FIG. 1A, a screen oxide layer (not shown) is formed on a semiconductor substrate 102. The screen oxide layer serves to prevent the interface of the semiconductor substrate 102 from being damaged at the time of a well ion implantation process or a threshold voltage ion implantation process that is subsequently performed. The well ion implantation process is performed so as to form well regions in the semiconductor substrate 102, and the threshold voltage ion implantation process is carried out so as to control the threshold voltage of semiconductor elements such as transistors. Thus, the well regions (not shown) are formed in the semiconductor substrate 102, and each well region can have a triple structure.

After the screen oxide layer is removed, a tunnel insulating layer 104 is formed on the semiconductor substrate 102. The tunnel insulating layer 104 functions as a tunnel insulating layer through which electrons pass from a channel junction formed on its lower side to a charge storage layer formed on its upper side. The tunnel insulating layer 104 is preferably formed of an oxide layer. A conductive layer 106 is formed on the tunnel insulating layer 104. The conductive layer 106 is used as a charge storage layer (for example, a floating gate) in which charges, received from the channel junction formed on the lower side of the tunnel insulating layer 104, are stored or from which charges stored therein can be removed. The conductive layer 106 is preferably formed of a polysilicon layer.

Referring to FIG. 1B, a hard mask pattern (not shown) is formed on the conductive layer 106. The hard mask pattern can be formed to open an isolation region of the semiconductor substrate 102. The conductive layer 106 and the tunnel insulating layer 104 are patterned by means of an etch process employing the hard mask pattern, and trenches are formed in the semiconductor substrate 102. At this time, the sidewall of the trench has an almost vertical slope angle.

Referring to FIG. 1C, a first insulating layer 108 is formed on the semiconductor substrate 102, including the trenches, and the conductive layer 106 is formed to a thickness in which the shape of the trenches can be maintained. The first insulating layer 108 is preferably formed of a silicon oxide (SiO₂) layer (for example, an O₃-TEOS oxide layer). At this time, the first insulating layer 108 has windings along the shape of the conductive layer 106. A slope angle of the first insulating layer 108, which is formed by the sidewalls of the first insulating layer 108, is almost vertical, and a space between the sidewalls of the first insulating layer 108 is narrow. Accordingly, when a second insulating layer is additionally formed on the first insulating layer 108 in a subsequent process, the space between the sidewalls of the first insulating layer 108 is rarely gap-filled with the second insulating layer.

Referring to FIG. 1D, NF₃ reacts with NH₃ over the semiconductor substrate 102, including the first insulating layer 108, in a plasma state, creating an etchant including NH₄F and NH₄F.HF. Referring to the following reaction equation 1, the etchant reacts with the surface of the first insulating layer 108, so that the surface of the first insulating layer 108 is substituted with salt 108a (for example, (NH₄)₂SiF₆).

NH₄F or NH₄F.HF+SiO₂→(NH₄)₂SiF₆ (solid)+H₂O [Reaction Equation 1]

At this time, the top surface of the first insulating layer 108 protrudes due to the shape of the first insulating layer 108, and is therefore exposed more to the etchant than to the sidewalls of the first insulating layer 108. Accordingly, a thickness of the top surface of the first insulating layer 108, which is substituted with the salt 108a, is thicker than that of the sidewalls of the first insulating layer 108.

Referring to FIG. 1E, if an annealing process (for example, heat at a temperature of 100 degrees Celsius to 700 degrees Celsius) is applied to the semiconductor substrate 102, the salt 108a (refer to FIG. 1D) is removed according to the following reaction equation 2.

(NH₄)₂SiF₆ (solid)→SiF4 (gas)+NH₃ (gas)+HF (gas) [Reaction Equation 2]

Accordingly, a part of the top surface of the first insulating layer 108 is removed, so that the slope angle formed by the sidewalls of the first insulating layer 108 becomes gentler. Thus, the space between the sidewalls of the first insulating layer 108 is further expanded.

Referring to FIG. 1F, a second insulating layer 110 is formed on the first insulating layer 108, fully gap-filling the trenches. The second insulating layer 110 is preferably formed of a silicon oxide (SiO₂) layer (for example, an O₃-TEOS oxide layer). At this time, since the space between the sidewalls of the first insulating layer 108 has been expanded by the above process, the second insulating layer 110 does not have void and/or seams and, therefore, can be easily gap-filled.

Meanwhile, when the trenches are gap-filled with the insulating layer, the steps of depositing the insulating layer on some of the trenches, performing dry etch on the insulating layer, and then depositing the insulating layer again can be performed repeatedly unlike the invention. In this case, however, there is a problem in that the tunnel insulating layer 104 is damaged by a fluorine-based gas (for example, NF₃ gas), which is used to perform dry etch on the insulating layer. However, the invention can easily gap-fill the trenches without damaging the tunnel insulating layer 104 by expanding the space between the sidewalls of the first insulating layer 108 without using the fluorine-based gas.

Referring to FIG. 1G, the first insulating layer 108 and the second insulating layer 110 formed over the conductive layer 106 are preferably removed by means of a polishing process such as CMP. Accordingly, isolation layers, respectively including the first insulating layer 108 and the second insulating layer 110, are formed in the isolation region of the semiconductor substrate 102.

Although the foregoing description has been made with reference to the specific embodiment, changes and modifications of the invention may be made by those of ordinary skill in the art without departing from the spirit and scope of the invention.

What is claimed is:

1. A method of forming isolation layers of a semiconductor device, the method comprising:
forming a first insulating layer on a semiconductor substrate including on trenches formed in the semiconductor substrate whereby the insulating layer defines a top surface and sidewalls on the trenches;
substituting the top surface of the first insulating layer with a salt;
removing the salt to expand a space between the sidewalls of the first insulating layer; and
forming a second insulating layer on the first insulating layer in order to gap-fill the trenches.

2. The method of claim 1, wherein the salt comprises (NH₄)₂SiF₆.

3. The method of claim 1, comprising removing the salt by an annealing process.

4. The method of claim 3, comprising performing the annealing process at a temperature of 100 degrees Celsius to 700 degrees Celsius.

5. The method of claim 1, at least one of the first insulating layer and the second insulating layer comprises an oxide layer.

6. The method of claim 1, wherein at least one of the first insulating layer and the second insulating layer comprises an O₃-TEOS oxide layer.

7. The method of claim 1, comprising reacting the top surface of the first insulating layer with an etchant and substituting the top surface with the salt.

8. The method of claim 7, comprising generating the etchant is by reacting NF₃ with NH₃ in a plasma state.

9. The method of claim 8, wherein the etchant comprises NH₄F or NH₄F.HF.

10. The method of claim 1, comprising forming the trenches by:
forming a tunnel insulating layer and a conductive layer over the semiconductor substrate; and
etching the conductive layer, the tunnel insulating layer, and the semiconductor substrate so that the isolation region of the semiconductor substrate is exposed, thereby forming the trenches.

11. The method of claim 1, comprising forming the first insulating layer to a thickness in which a shape of the trench can be maintained.
